(19) United States
(12) Patent Application Publication
(10) Pub. No.: US 2025/0380390 A1
(43) Pub. Date: Dec. 11, 2025

(54) DISPENSER HEATING FOR COLD TEMPERATURES

(71) Applicant: Caterpillar Inc., Peoria, IL (US)

(72) Inventors: Travis Stephen Bengtson, Washington, IL (US); Andrew William Paxson, Tucson, AZ (US); Martin Castonguay, Blainville (CA); Yannick Lacas, Blainville (CA); John Vitale, Sahuarita, AZ (US)

(73) Assignee: Caterpillar Inc., Peoria, IL (US)

(21) Appl. No.: 19/208,145

(22) Filed: May 14, 2025

Related U.S. Application Data
(60) Provisional application No. 63/657,560, filed on Jun. 7, 2024.

(51) Int. Cl. H05K 7/20; H02J 7/00

(52) U.S. Cl. CPC H05K 7/20909; H02J 7/0042

(57) ABSTRACT

An electrical dispenser can include a main enclosure including a plurality of separate cabinets, a plurality of heaters within one or more of the separate cabinets, a plurality of internal temperature sensors within one or more of the cabinets, an external humidity sensor and external temperature sensor, one or more fans to move air through the main enclosure and the plurality of separate cabinets, and a controller within the main enclosure and coupled to the plurality of heaters, the external humidity sensor and the external temperature sensor, the plurality of internal temperature sensors, and the one or more fans, wherein the controller is configured to receive each input from the external humidity sensor, the external temperature sensor, and the plurality of internal temperature sensors and to control the plurality of heaters and the one or more fans such that a temperature in each of the separate cabinets reaches at least an operating temperature.

### CLAIM OF PRIORITY

This application claims the benefit of U.S. Provisional Patent Application Ser. No. 63/657,560, filed on Jun. 7, 2024, the benefit of priority of which is claimed hereby, and which is incorporated by reference herein in its entirety.

### TECHNICAL FIELD

This document relates to electric powered work machines and in particular to a Megawatt class charge dispenser system for charging the energy source of battery electric machines.

### BACKGROUND

Powering a large moving work machine (e.g., a wheel loader, a mining truck, etc.) with one or more electric motors requires a large mobile electric energy source that can provide current of thousands of Amperes (Amps). An example of a mobile energy source is a battery system containing multiple strings of high-capacity batteries. The batteries in each string are connected in series, and the strings of batteries are connected in parallel to provide the high output power needed by the electric work machines. The electric work machines can be charged by using an electric dispenser operatively coupled to the batteries. In cold operating conditions, the electric dispenser needs to be warmed up to perform properly.

### SUMMARY

In an example according to this disclosure, an electrical dispenser can include a main enclosure including a plurality of separate cabinets, a plurality of heaters within one or more of the separate cabinets, a plurality of internal temperature sensors within one or more of the cabinets, an external humidity sensor and external temperature sensor, one or more fans to move air through the main enclosure and the plurality of separate cabinets, and a controller within the main enclosure and coupled to the plurality of heaters, the external humidity sensor and the external temperature sensor, the plurality of internal temperature sensors, and the one or more fans, wherein the controller is configured to receive each input from the external humidity sensor, the external temperature sensor, and the plurality of internal temperature sensors and to control the plurality of heaters and the one or more fans such that a temperature in each of the separate cabinets reaches at least an operating temperature.

In another example according to the present disclosure, a method for controlling an electrical dispenser can include determining an external humidity and an external temperature, determining a plurality of internal temperatures within one or more of a plurality of cabinets within a main enclosure, and controlling a plurality of heaters and one or more fans within the main enclosure and within one or more of the plurality of cabinets such that the temperature in each of the cabinets reaches at least an operating temperature.

In another example according to the present disclosure, a system for controlling an electrical dispenser can include a plurality of heaters within one or more separate cabinets of a main enclosure, an external humidity sensor and external temperature sensor, a plurality of internal temperature sensors within one or more of the cabinets, one or more fans to move air through the main enclosure and the plurality of separate cabinets, a controller within the main enclosure and coupled to the plurality of heaters, the external humidity sensor, the external temperature sensor, the plurality of internal temperature sensors, and the one or more fans, wherein the controller is configured to receive each input from the external humidity sensor, the external temperature sensor, and the plurality of internal temperature sensors and to control the plurality of heaters and the one or more fans such that the temperature in each of the separate cabinets reaches at least an operating temperature.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 shows a side view of a work machine, in accordance with one embodiment.

FIG. 2 shows an example charging system for battery electric machines in accordance with this disclosure, in accordance with one embodiment.

FIG. 3 is a block diagram of an example of portions of a charge dispenser, in accordance with one embodiment.

FIG. 4 shows a front perspective view of a dispenser, in accordance with one embodiment.

FIG. 5 shows a rear perspective view of the dispenser, in accordance with one embodiment.

FIG. 6 shows a front perspective view showing certain details of the dispenser with the front panels removed, in accordance with one embodiment.

FIG. 7 shows another front perspective view showing certain details of the dispenser, in accordance with one embodiment.

FIG. 8 shows a rear perspective view of the dispenser with the panels removed showing further details, in accordance with one embodiment.

FIG. 9 is a schematic diagram of the power and heating layout of the dispenser, in accordance with one embodiment.

FIG. 10 shows a method for operating a dispenser, in accordance with one embodiment.

### DETAILED DESCRIPTION

Examples according to this disclosure are directed to methods and devices that improve charging of a rechargeable energy source of an electric work machine.

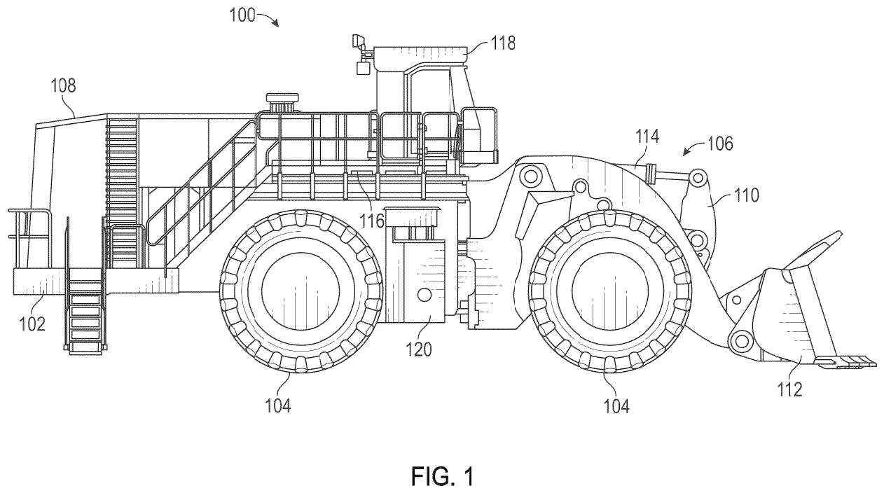

FIG. 1 depicts an example machine 100 in accordance with this disclosure. In FIG. 1, machine 100 includes frame 102, wheels 104, implement 106, and a speed control system implemented in one or more on-board electronic devices like, for example, an electronic control unit or ECU. Example machine 100 is a wheel loader. In other examples, however, the machine may be other types of machines related to various industries, including, as examples, construction, agriculture, forestry, transportation, material handling, waste management, marine, stationary power, and so on. Accordingly, although some examples are described with reference to a wheel loader machine, examples according to this disclosure are also applicable to other types of machines including graders, scrapers, dozers, excavators, compactors, material haulers like dump trucks, marine vessels, locomotives, along with other example machine types.

Machine 100 includes frame 102 mounted on four wheels 104, although, in other examples, the machine could have more than four wheels. Frame 102 is configured to support and/or mount one or more components of machine 100. For example, machine 100 includes enclosure 108 coupled to frame 102. Enclosure 108 can house, among other components, an electric motor to propel the machine over various terrain via wheels 104. In some examples, multiple electric motors are included in multiple enclosures at multiple locations of the machine 100.

Machine 100 includes implement 106 coupled to the frame 102 through linkage assembly 110, which is configured to be actuated to articulate bucket 112 of implement 106. Bucket 112 of implement 106 may be configured to transfer material such as, soil or debris, from one location to another. Linkage assembly 110 can include one or more cylinders 114 configured to be actuated hydraulically or pneumatically, for example, to articulate bucket 112. For example, linkage assembly 110 can be actuated by cylinders 114 to raise and lower and/or rotate bucket 112 relative to frame 102 of machine 100.

Platform 116 is coupled to frame 102 and provides access to various locations on machine 100 for operational and/or maintenance purposes. Machine 100 also includes an operator cabin 118, which can be open or enclosed and may be accessed via platform 116. Operator cabin 118 may include one or more control devices (not shown) such as, a joystick, a steering wheel, pedals, levers, buttons, switches, among other examples. The control devices are configured to enable the operator to control machine 100 and/or the implement 106. Operator cabin 118 may also include an operator interface such as, a display device, a sound source, a light source, or a combination thereof.

Machine 100 can be used in a variety of industrial, construction, commercial or other applications. Machine 100 can be operated by an operator in operator cabin 118. The operator can, for example, drive machine 100 to and from various locations on a work site and can also pick up and deposit loads of material using bucket 112 of implement 106. By further way of example, both operation by a remotely located operator and autonomous or robotic operation are contemplated. Machine 100 can be used to excavate a portion of a work site by actuating cylinders 114 to articulate bucket 112 via linkage assembly 110 to dig into and remove dirt, rock, sand, etc. from a portion of the work site and deposit this load in another location. Machine 100 can include a battery compartment connected to frame 102 and including a battery system 120. Battery system 120 is electrically coupled to the one or more electric motors of the battery electric machine (BEM) 100.

The battery system of different types of battery electric machines (BEMs) machines may have different charging needs. The battery system may differ in the amount of charge needed to fully charge the battery system, the rate at which the battery system can be charged, etc.

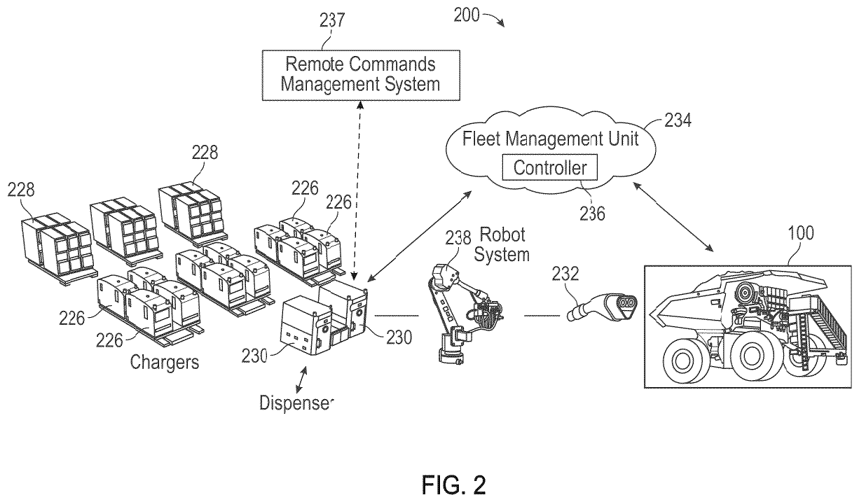

FIG. 2 is a diagram of an example of a charging system 200 for a BEM 100. The system 200 includes multiple charger devices 226. Each charger device 226 is configured to provide high-capacity charge energy for charging a BEM 100. Each of the charger devices 226 can be coupled to one or more switch devices 228 that connect the charger device to a grid, a generator set device, etc. The charging system 200 also includes one or more charge dispensers 230. Multiple charger devices 226 are connected to one charge dispenser 230. The example system of FIG. 2 includes two charge dispensers and one to six charger devices 226 are connected to one charge dispenser 230 in the example.

When charging, a charge dispenser 230 is connected to the BEM 100 by a charging cable 232 and plug. The charging cable 232 may be air-cooled or liquid-cooled depending on the capacity of the charging cable 232. A charge dispenser 230 aggregates the charging energy from the charger devices 226 connected to it to provide the aggregated charging energy to the BEM 100 through the charging cable 232. This makes the charging system 200 modular and charging energy from one to six charger devices 226 can be aggregated in the example system of FIG. 2. In some examples, more than six charger devices 226 can be connected to one charge dispenser 230 and the charge from more than six charger devices can be aggregated by the charge dispenser 230.

The BEMs 100 being charged may be automated and may operate without a human operator. Operation of the BEMs may be through a fleet management unit 234. The fleet management unit 234 may be implemented through one or more servers located at the remote site, or through one or more servers that are cloud-based. The fleet management unit 234 manages the displacements of the automated BEMs at the job site. The fleet management unit 234 may include a fleet controller 236 to communicate with the BEMs 100 and charge dispenser 230 wirelessly (e.g., wireless WiFi). The fleet management unit 234 sends specific instructions to the BEMs to move them on specific lanes across the job site. When the fleet management unit 234 determines that a BEM needs charging, the fleet management unit 234 may match a BEM to a charge dispenser 230 based on the charge dispenser's location, availability, and capacity. The charging system 200 may include a robotic connector system 238. The robotic connector system 238 connects and disconnects the charging cable 232 from the receptacle of the BEM 100 in response to commands.

The fleet management unit 234 informs the charge dispenser 230 of the arrival of a BEM 100. When the BEM 100 is ready to be charged, the charge dispenser 230 requests the robotic connector system 238 to connect the charging cable 232 to the BEM 100. Upon connection, the charge dispenser 230 will automatically start a charging session. On completion, the charge dispenser 230 will request the robotic connector system 238 to disconnect the cable 232 and move back to stow position. The charge dispenser 230 may then inform the fleet management unit 234 that the BEM 100 can leave. All these operations can be executed without the help of a human operator on site.

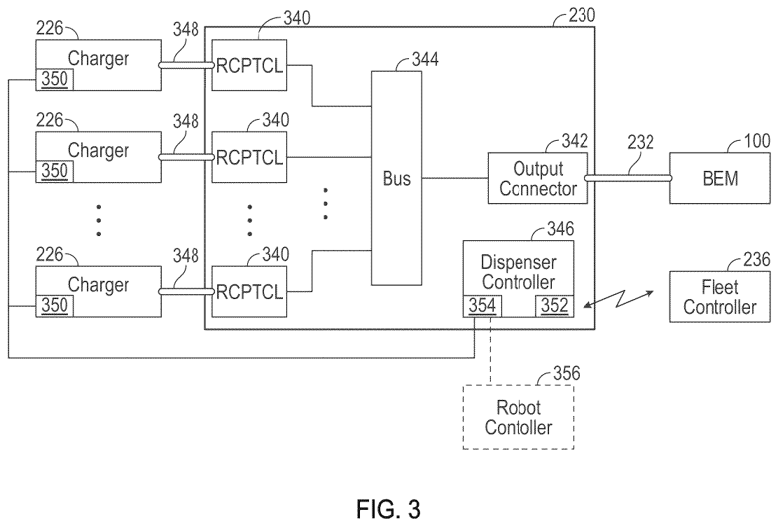

FIG. 3 is a block diagram of an example of portions of a charge dispenser 230. The charge dispenser 230 includes multiple charger input receptacles 340 to receive electrical energy from multiple charger devices 226. Each of the charger devices 226 can provide energy to charge a BEM 100. The charger devices can include power converters to produce the charge energy. The charger devices 226 are connected to the charger input receptacles 340 by charger cables 348. The charge dispenser 230 may send commands to the charger devices 226 to set the output of the power converters to a voltage and current appropriate for the type of BEM 100 being charged. The charge dispenser 230 includes a cable output connector 342 to connect to a charging cable 232 that is connectable to the BEM 100. The charge dispenser 230 can include a dispenser bus 344 that provides accumulated charger energy to the cable output connector 342.

The charge dispenser 230 also includes a dispenser controller 346 and the charger devices 226 each include a charger controller 350. A controller includes processing circuitry that includes one or more processors (e.g., microprocessors, digital signal processors (DSP), application specific integrated circuits (ASICs), a programmable gate arrays (PGAs), or equivalent discrete or integrated logic circuitry. A controller can include memory to store instructions performable by the processing circuitry. The instructions may be software or firmware instructions and the instructions configure the processing circuitry to perform the functions described for the processing circuitry.

The dispenser controller 346 includes a wireless communication port 352 to communicate information wirelessly with the fleet management unit 234 using a wireless communication network (e.g., using a WiFi network). The dispenser controller 346 includes another communication port 354 to communicate information with the charger controllers 350 of the charger devices 226. The dispenser controller 346 and the charger controllers 350 may communicate using another communication network such as an Ethernet network.

The charging system 200 can include a remote commands management system 237 to communicate commands wirelessly with the dispenser controller 346. The communication link with the remote commands management system 237 allows for remote control of the charge dispenser 230. A user may send commands remotely to the charge dispenser 230 through the remote commands management system 237. A user may access the remote commands management system 237 through the Internet by accessing a website. The devices for a job site may be displayed on the website. The user may select a charge dispenser 233, and send commands to start, stop, etc. The dispenser controller 346 accounts for conditions necessary to execute the command (e.g., cable is connected, charging request received, etc.). Given proper validations of the conditions for charging, the dispenser controller 346 can then execute received commands. This allows the user to control the charging system 200 remotely without having to physically go to the location of the system, which may be a large mining site or underground mining site.

In one example, the dispenser controller 346 controls the charging of the BEM 100. The dispenser controller 346 receives an indication (e.g., a charge message or charge command) from the fleet controller 236 of the fleet management unit 234 to start a charging session with the BEM 100. In response, the dispenser controller 346 determines if the BEM 100 is connected for charging. The dispenser controller 346 receives charging information from the BEM 100. The charging information may be different for different types of BEMs. The BEM 100 may include a charge interface controller (CIC) that sends the charging information to the dispenser controller 346. The charging information may include one or more of power, current, or voltage required for the charging of the machine. The charging information may include a state of charge (SOC) of the battery system 120 of the BEM 100.

The dispenser controller 346 uses the charging information to send one or more activation messages to the charger controllers 350 to activate or bring onboard multiple charger devices 226. The dispenser controller 346 may activate or bring onboard all the charger devices 226 for the charging session or activate a multiple number of chargers less than all the charger devices 226. The charge dispenser 230 receives the charging energy from the activated or onboard charger devices 226 and delivers the charging energy to the BEM 100 via the charging cable 232 during the charging session. At any time during the charging session, the dispenser controller 346 may change operation of the charger devices 226. For instance, the dispenser controller 346 may reduce the number of activated charger devices 226, increase the number of activated charger devices 226, or replace a charger device 226 during a charging session. Also, the dispenser controller 346 may adjust the charging energy output of one or more of the activated charger devices 226 during the charging session.

There may be several reasons for the dispenser controller 346 to change or adjust the activation of the charger devices 226 during a charging session. The change or adjustment of the charger devices may be in response to a scheduled change in the charging profile during a charging session. For example, the charging profile may include delivering more charge energy at the beginning of the charging session and reducing the charge energy later in the charging session. The dispenser controller 346 changes the charging configuration of the charger devices 226 in response to the change in demand of charging energy.

In another example, the dispenser controller 346 may detect a fault in one or more charger devices 226, and may deactivate the defective charger devices 226 and activate replacement charger devices 226. The dispenser controller 346 may detect a change (e.g., a decrease) in charge capability of one or more charger devices 226 and send one or more activation messages to change (e.g., increase) the number of active charger devices 226 in response.

The dispenser controller 346 may adjust the charging energy output of one or more of the activated charger devices 226 during the charging session to balance the load among the onboard charging devices 226. Balancing the load during a charging session may be useful to extend the operating life of the charger devices 226.

The dispenser controller 346 may adjust the charging energy output of one or more of the activated charger devices 226 during the charging session in response to temperature information. The dispenser controller 346 may receive temperature information regarding the charging cable 232 (e.g., from one or more temperature sensors monitoring temperature of the charging cable 232). If the temperature increases above a predetermined threshold the dispenser controller may adjust the charging energy output of the charger devices 226 to reduce charging energy in the charging cable 232 or deactivate a charger device 226 to reduce charging energy in the cable. The dispenser controller 346 may also change operation of a cable cooling system to address the increase in cable temperature.

The dispenser controller 346 may adjust the charging energy output of one or more of the activated charger devices 226 during the charging session based on the power derating of the system. For instance, the dispenser controller 346 may adjust the output of the onboard charger devices 226 when power output of the charge dispenser 230 nears a maximum power rating of the charge dispenser 230. The dispenser controller 346 may adjust the output of the onboard charger devices 226 when the output of the charge dispenser 230 nears a maximum power rating of the BEM 100. The dispenser controller 346 may receive an alert of reaching the power limit of the BEM 100 from the CIC of the BEM 100. The dispenser controller 346 uses the power derating information of the charge dispenser 230 or the BEM 100 to automatically adjust power output in real-time. The power derating values for the BEM 100 may increase or decrease at any time. The power derating of the charge dispenser 230 may be a set value unless changed by a user on site or through the fleet management unit 234.

The dispenser controller 346 may also adjust the charging energy output of one or more of the activated charger devices 226 during the charging session in response to external commands (e.g., commands from the fleet management unit 234) based on conditions of the job site. The external commands may be received wirelessly over-the-air to instruct the charge dispenser 230 to limit power output.

As explained previously herein regarding FIG. 2, the charging system 200 can include a robotic connector system 238 to connect and disconnect the charging cable 232 to a charging receptacle of the BEM 100. The robotic connector system 238 includes a robotic controller 356. To start the charging session in response to the indication from the fleet controller 236 to do so, the dispenser controller 346 sends a connect message to the robot controller 356 and the robotic connector system 238 changes from a storage position to connect the charging cable to the BEM 100. The dispenser controller 346 may automatically detect connection of the charging cable 232. For instance, connection of the charging cable 232 to the BEM 100 may cause a connection signal (e.g., sent from the BEM 100) to be detected by the dispenser controller 346. The dispenser controller 346 may proceed to the next step of the charging session (e.g., receiving charge information from the CIC of the BEM 100 in response to detecting that the charging cable 232 is connected.

Accordingly, in summary, at a work-site the charge dispenser 230 can include multiple charger input receptacles 340 to receive electrical energy from multiple charger devices 226, wherein each charger device 226 is configured to provide energy to charge the BEM 100. The charging cable 232 is operatively coupled to the charger devices 226 and the charging cable 232 is connectable to the BEM 100. The dispenser controller 346 can be configured to receive an indication from a fleet controller of a fleet management unit to start a charging session with the BEM 100, determine when the BEM 100 is connected for charging, receive charging information for the BEM 100, activate a multiple number of charger devices 226 for the charge dispenser 230 to receive charging energy from the charger devices 226 in parallel, and deliver the charging energy to the BEM 100 during the charging session, change the number of charger devices 226 activated during the charging session, and send an indication to the fleet controller when charging of the BEM 100 is complete.

As noted, in cold operating conditions, the charge dispenser 230 needs to be warmed up to perform properly before any charging is performed. Accordingly, a system of heaters and fans can be utilized to warm up the charge dispenser 230 to a proper operating temperature.

As will be discussed in detail below, the charge dispenser 230 can be equipped with multiple temperature sensors, heating elements and fans to ensure safe operating conditions. The objective is to have the system being able to operate when outside temperature is above-40C. Moreover, dew point temperature must be accounted for as condensation can occur at any temperature and cause short circuits with such a high-power system.

Accordingly, the system can be configured to constantly monitor the sensors and adjust heating and ventilation to heat and/or dehumidify the dispenser 230. The system will also calculate dynamically the operational condition of the system and prevent any charge in case of problem. For example, before starting a charging session, the dispenser controller 346 can perform an environmental check procedure to detect any environmental faults conditions prior to entering the charging session.

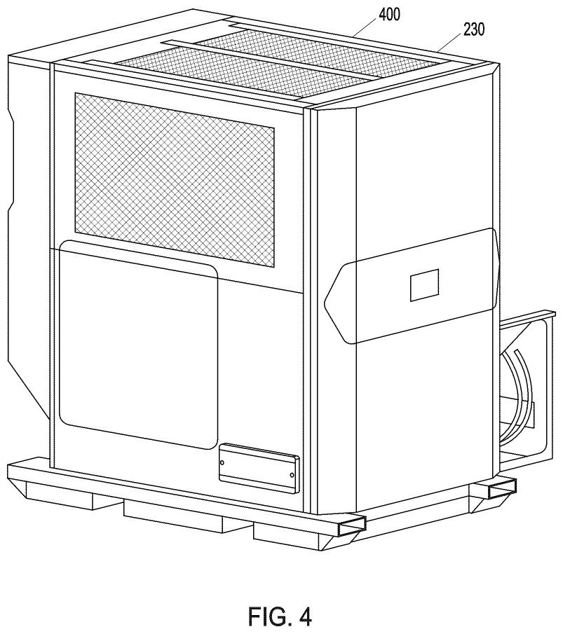

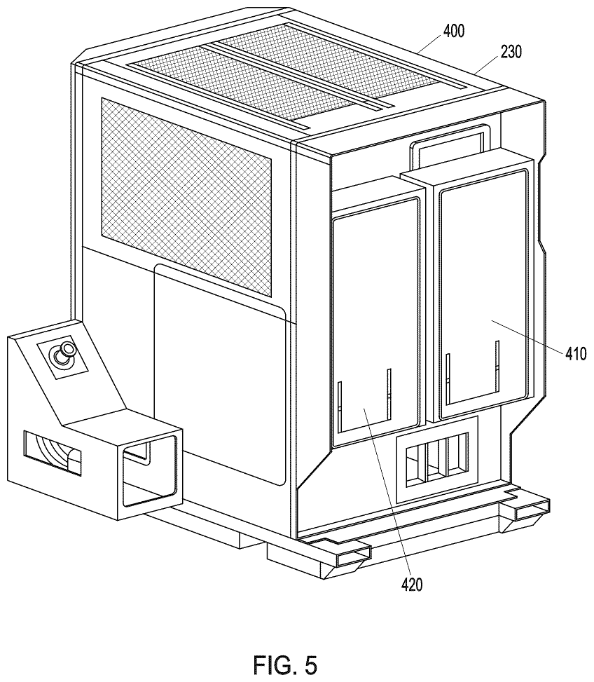

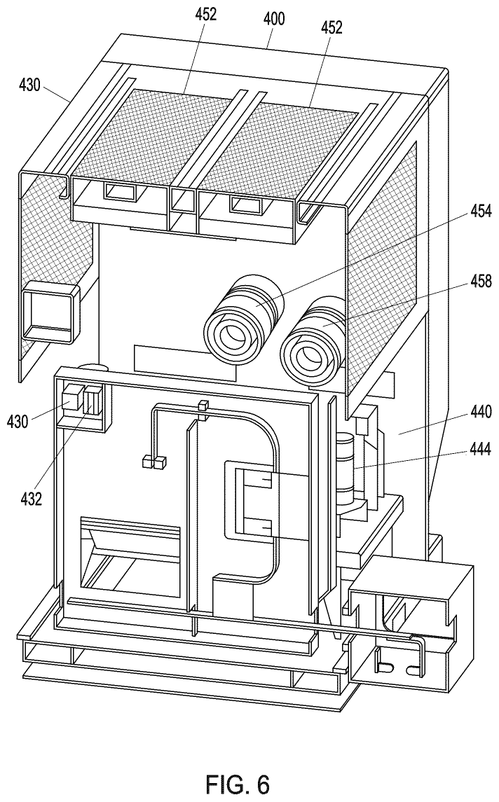

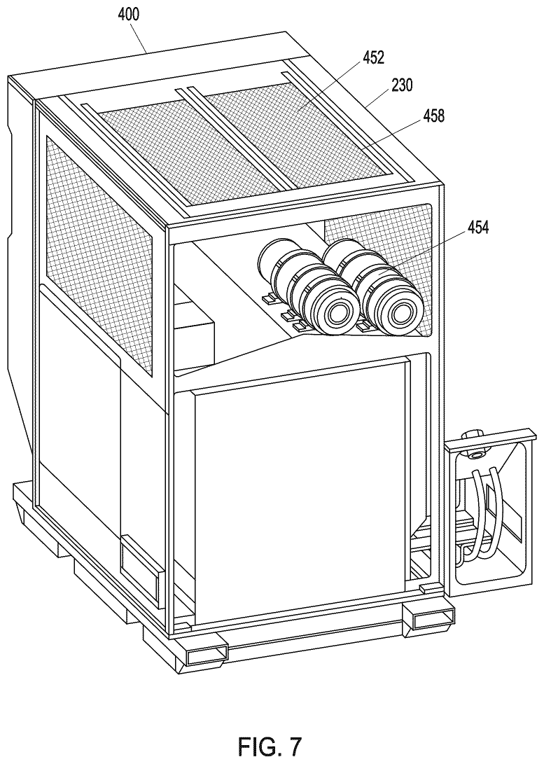

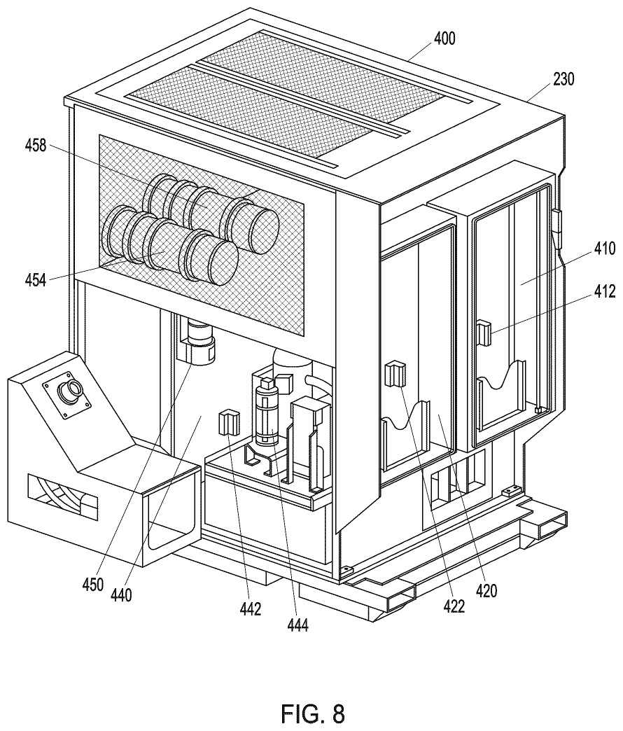

FIGS. 4-8 show details of an example charge dispenser 230. FIG. 4 shows a front perspective view of the charge dispenser 230; FIG. 5 shows a rear perspective view of the dispenser 230; FIG. 6 shows a front perspective view showing certain details of the dispenser 230; FIG. 7 shows another front perspective view showing certain details of the dispenser 230; and FIG. 8 shows a rear perspective view of the dispenser 230 showing further details, in accordance with one embodiment.

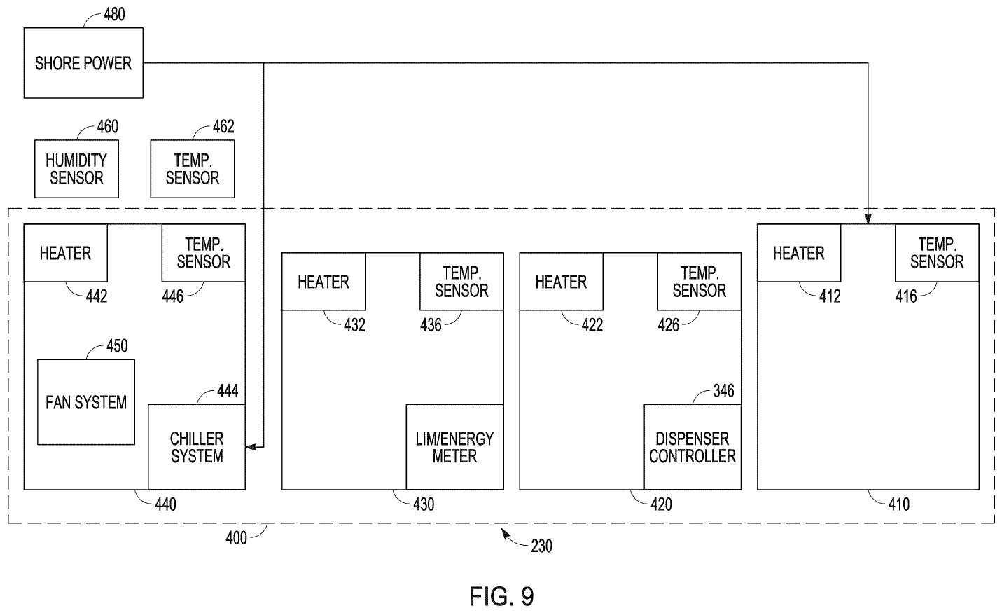

In general, the example charge dispenser 230 can include a main enclosure 400 having a plurality of separate sub-enclosures or cabinets. For example, the main enclosure 400 can contain a first cabinet 410, in an example, the cabinet 410 can include a 480V cabinet which functions as a power supply for the charge dispenser 230 and receives 480/400 VAC power from an external power source 480 (See FIG. 9). As will be further described below in FIG. 9, the cabinet 410 can include an air temperature sensor, an optional thermostat, and a heater 412. The main enclosure 400 can further include a cabinet 420. The cabinet 420 can include a 50V cabinet and can include components such as a heater 422, an air temperature sensor, and the dispenser controller 346 (FIG. 3).

The main enclosure 400 can further include a cabinet 430. The cabinet 430 include components such as a line isolation monitor (LIM), an energy meter, an air temperature sensor, and a heater 432.

The main enclosure can further include a cabinet 440. The cabinet 440 can function as a main enclosure for a chiller system 444. The chiller system 444 is configured to provide liquid cooling to chill the charging cable 232 that hooks up to the BEM 100. (See FIG. 3). The cabinet 440 can further include an air temperature sensor and a heater 442.

Accordingly, the example charge dispenser 230 can include the main enclosure 400 including the plurality of separate cabinets 410, 420, 430, 440. There can be the plurality of heaters 412, 414, 414, 424 within the charge dispenser 230 with zero to one or more heaters within each cabinet.

For example, in one embodiment, the heater 412 of cabinet 410 can be omitted and the cabinets 410 and 440 are configured such that the heater 442 of cabinet 440 also heats cabinet 410.

The charge dispenser 230 can also include one or more air movers or fans, such as intake fans, recirculating fans, and pre-cleaners, configured to move air through the main enclosure 400 and the plurality of separate cabinets 410, 420, 430, 440.

For example, the air movers can be configured such that one fan 450, such as a recirculating fan, is placed within the cabinet 440 to recirculate air through the cabinet 440 and the rest of the main enclosure 400. Intake fans 452 can be also placed above the cabinet 440 on top of the charge dispenser 230. The fans 452 can draw air into the dispenser 230 through fan grills 458 on an outer surface of the dispenser 230. The fan 450 can recirculate air through the dispenser 230. The system can also provide one or more pre-cleaners 454 located above cabinet 440 to preclean the air and remove dust and water from the incoming air.

As will be further detailed below, the heaters 412, 422, 432, 442, and the fans 450, 452, 454 are operatively coupled to the dispenser controller 346, and the controller 346 can be configured to operate the heaters and fans as necessary (based on input from the various sensors) to provide a proper operating environment for the machine dispenser 230.

### INDUSTRIAL APPLICABILITY

The present system is applicable during many situations. For example, when charge dispenser system is needed for charging the energy source of a plurality of battery electric machines.

FIG. 9 is a schematic diagram of the power and heating layout of the charge dispenser 230, in accordance with one embodiment.

Shown schematically are the separate cabinets 410, 420, 430, 440 within the main enclosure 400 that were discussed above. Here, the dispenser 230 receives external power from a shore power source 480. The shore power source 480 is separate from the charger devices 226 discussed above. In an example, the power delivered to the first cabinet 410 can be 480/400 VAC. In one example, power can also be directly delivered to the chiller system 444. The cabinet 410 then distributes power at various levels to the various components throughout the rest of the cabinets 420, 430, 440 and other areas of the dispenser 230 through a plurality of electrical lines (not shown).

Here, the system can include an external humidity sensor 460 and external temperature sensor 462. These components are outside of the main enclosure 400 and can be used to measure the air temperature and the relative humidity of the ambient air outside the charge dispenser 230. The sensors 460 and 462 can be coupled to the dispenser controller 346.

The system can further include a plurality of internal temperature sensors within one or more of the cabinets 410, 420, 430, 440. For example, each cabinet can include a separate temperature sensor 416, 426, 436, and 446, respectively. Each of the temperature sensors are operatively coupled to the dispenser controller 346.

Accordingly, the dispenser controller 346 can receive the temperature information from each cabinet, and the external temperature and the external relative humidity from the external sensors 460, 462.

The controller 346 can be operatively coupled to the heaters 412, 422, 432, 442, and the fans 450, 452, 454. Based on the input information from the sensors, the controller 346 can operate one or more of the plurality of heaters 412, 422, 432, 442, and the fan system including one or more of the plurality of fans 450, 452, 454 to allow the dispenser 230 to be at a proper operating environmental condition.

Thus, the controller 346 can be coupled to the plurality of heaters, the external humidity sensor and the external temperature sensor, the plurality of internal temperature sensors, and the plurality of fans, and the controller 346 can be configured to receive each input from the external humidity sensor 460 and the external temperature sensor 462, the plurality of internal temperature sensors and then control the plurality of heaters and the plurality of fans such that the temperature in each of the separate cabinets reaches to at least a pre-determined operating temperature.

In one example, the operating temperature is set to at least 0° C. for at least one of the separate cabinets and is set to at least −20° C. for at least another one or more of the separate cabinets. For example, the cabinet 440 can be set to at least-20° C. and the cabinets 410, 420, 430 can be set to at least 0° C. In some examples, thermostats can be integrally incorporated into the heaters. In other examples, the controller 346 acts as the thermostat for each heater.

In one example, the controller 346 can determine the operating temperature as the point when the temperature within each of the separate cabinets is above the present dew point. The dew point can be determined by the controller 346 using the external humidity sensor and the external temperature sensor. The dew point is the temperature the air needs to be heated to in order to achieve a relative humidity (RH) of 100%. At this point the air is able to hold water in the gas form. If the air were any cooler, water vapor would have to come out of the atmosphere in the liquid form, usually as condensation or frost. The dew point when water is below freezing is typically called the frost point, however, for the sake of this application dew point and frost point will be used interchangeably. In general, the dew point is affected by the air's humidity. The more moisture the air contains, the higher its dew point,

Accordingly, in one example, the controller 346 can be configured to operate the one or more heaters 412, 422, 432, 442 and the fans until the temperature of each of the separate cabinets is above the present dew point before operating the charge dispenser 230. Thus, the heaters and fans can be operated by the controller 346 to heat and/or dehumidify the air within the dispenser 230.

In one example, the heater 412 in the first cabinet 410 can include a 100 W heater. In one example, the heater 412 can include a 650 W heater. In one example, the first cabinet 410 can include both types of heaters. In another embodiment, the first cabinet 410 does not have a heater. In some embodiments, the heater 422 can include a 650 W heater, the heater 432 can include a 100 W heater, and the heater 442 can include a 1200 W heater. The heaters can be used for heating the air and/or for dehumidification purposes. The various heaters can include integral thermostats and/or be controlled by the controller 346.

In one example, the controller 346 can be configured to disable charging to a BEM 100 by the charge dispenser 230 if an environmental condition of the system is not right. For example, if the temperature is too cold, and/or the dew point has not been reached, thus allowing condensation to form. Thus, the controller 346 is configured determine such an environmental fault condition and to disable charging if the environmental fault condition exists.

When started up, or when a charge to a BEM is called for, the controller 346 can perform an environmental check to determine if a fault condition exists where there would be moisture or condensation if the machine were to start charging. The controller 346 can then disable charging until the fault condition goes away or is otherwise remedied. Further, the controller 346 can continuously perform the environmental fault check, by continually monitoring the external and internal temperatures and the relative humidity, and can disable the dispenser 230 from operating at any time a fault condition exists.

In some examples, the controller 346 continuously monitors the external humidity sensor and the external temperature sensor, and the plurality of internal temperature sensors and adjusts the plurality of heaters and the plurality of fans such that the temperature in each of the separate cabinets remains at least at a minimum pre-determined operating temperature.

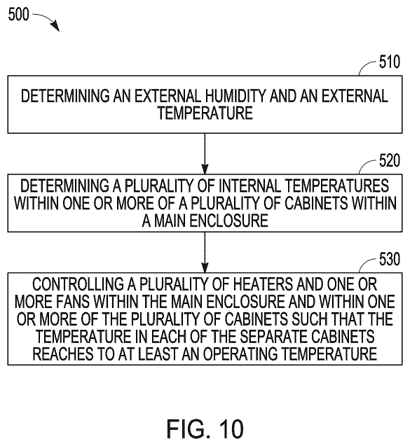

FIG. 10 shows a method for operating a dispenser, in accordance with one embodiment.

Referring to the discussion above, a method (500) for controlling an electrical dispenser can include determining an external humidity and an external temperature (510), determining a plurality of internal temperatures within one or more of a plurality of cabinets within a main enclosure (520), and controlling a plurality of heaters and one or more fans within the main enclosure and within one or more of the plurality of cabinets such that the temperature in each of the separate cabinets reaches to at least an operating temperature (530).

In various examples of operating the method, the operating temperature can be set to at least 0° C. for at least one of the separate cabinets and is set to at least −20° C. for at least another one or more of the separate cabinets. The operating temperature can be determined as the point when the temperature within each of the separate cabinets is above the present dew point.

The controller can be configured to disable charging if an environmental condition of the system is not right. The controller is configured determine an environmental fault condition and to disable charging if the environmental fault condition exists.

The method can include continuously monitoring the external humidity sensor and the external temperature sensor, and the plurality of internal temperature sensors and adjusts the plurality of heaters and the plurality of fans such that the temperature in each of the separate cabinets remains at least at a minimum pre-determined operating temperature.

In summary, in cold operating conditions, the charge dispenser 230 needs to be warmed up to perform properly. The dispenser 230 can be equipped with multiple temperature sensors, heating elements and recirculation fans to ensure safe operating conditions. The objective is to have the system being able to operate when outside temperature is at −40C (and above). Moreover, the dew point temperature must be accounted for as condensation can occur at any temperature and cause short circuits with such a high-power system.

The system can constantly monitor the sensors and adjust heating and ventilation. The system can also calculate dynamically the operational condition of the system and prevent any charge in case of a fault condition.

Various examples are illustrated in the figures and foregoing description. One or more features from one or more of these examples may be combined to form other examples.

The above detailed description is intended to be illustrative, and not restrictive. The scope of the disclosure should, therefore, be determined with references to the appended claims, along with the full scope of equivalents to which such claims are entitled.

What is claimed is:

1. An electrical dispenser comprising:
a main enclosure including a plurality of separate cabinets;
a plurality of heaters within one or more of the separate cabinets;
a plurality of internal temperature sensors within one or more of the cabinets;
an external humidity sensor and external temperature sensor;
one or more fans to move air through the main enclosure and the plurality of separate cabinets; and
a controller within the main enclosure and coupled to the plurality of heaters, the external humidity sensor and the external temperature sensor, the plurality of internal temperature sensors, and the one or more fans;
wherein the controller is configured to receive each input from the external humidity sensor, the external temperature sensor, and the plurality of internal temperature sensors and to control the plurality of heaters and the one or more fans such that a temperature in each of the separate cabinets reaches at least an operating temperature.

2. The dispenser of claim 1, wherein the operating temperature is set to at least 0° C. for at least one or more of the separate cabinets and is set to at least −20° C. for at least another one or more of the separate cabinets.

3. The dispenser of claim 1, wherein the operating temperature is determined by the controller as a point when the temperature within each of the separate cabinets is above a present dew point.

4. The dispenser of claim 3, wherein the controller is configured to control the one or more heaters until the temperature of each of the separate cabinets is above the present dew point.

5. The dispenser of claim 1, wherein the dispenser is coupled to an external power source and coupled to one or more electrical charger devices.

6. The dispenser of claim 1, wherein the plurality of cabinets includes a first cabinet, a second cabinet with a first heater, a LIM/Energy meter box cabinet with a second heater, and a chiller system cabinet with a third heater, wherein the chiller system cabinet third heater is positioned and configured to also heat the first cabinet.

7. The dispenser of claim 1, wherein the controller is configured to determine an environmental fault condition and to disable charging if a fault condition exists.

8. The dispenser of claim 1, wherein the controller continuously monitors the external humidity sensor, the external temperature sensor, and the plurality of internal temperature sensors and adjusts the plurality of heaters and the one or more fans such that the temperature in each of the separate cabinets remains at least at a minimum operating temperature.

9. The dispenser of claim 1, wherein the dispenser further includes multiple charger input receptacles to receive electrical energy from multiple charger devices, wherein each charger device is configured to provide energy to charge a BEM, and a cable connector configured to connect to a charging cable, wherein the charging cable is connectable to the BEM.

10. A method for controlling an electrical dispenser, the method comprising:
determining an external humidity and an external temperature;
determining a plurality of internal temperatures within one or more of a plurality of cabinets within a main enclosure; and
controlling a plurality of heaters and one or more fans within the main enclosure and within one or more of the plurality of cabinets such that the temperature in each of the cabinets reaches at least an operating temperature.

11. The method of claim 10, wherein the operating temperature is set to at least 0° C. for at least one of the cabinets and is set to at least −20° C. for at least another one or more of the cabinets.

12. The method of claim 10, wherein the operating temperature is determined as a point when the temperature within each of the cabinets is above a present dew point as determined from the external temperature and the external humidity.

13. The method of claim 10, wherein the controller is configured determine an environmental fault condition and to disable charging if the environmental fault condition exists.

14. The method of claim 10, including continuously monitoring the external humidity and the external temperature, and the plurality of internal temperatures and adjusting the plurality of heaters and the one or more fans such that the temperature in each of the cabinets remains at least at a minimum operating temperature.

15. A system for controlling an electrical dispenser, comprising:
a plurality of heaters within one or more separate cabinets of a main enclosure;
an external humidity sensor and external temperature sensor;
a plurality of internal temperature sensors within one or more of the cabinets;
one or more fans to move air through the main enclosure and the plurality of separate cabinets; and
a controller within the main enclosure and coupled to the plurality of heaters, the external humidity sensor, the external temperature sensor, the plurality of internal temperature sensors, and the one or more fans;
wherein the controller is configured to receive each input from the external humidity sensor, the external temperature sensor, and the plurality of internal temperature sensors and to control the plurality of heaters and the one or more fans such that the temperature in each of the separate cabinets reaches at least an operating temperature.

16. The system of claim 15, wherein the operating temperature is set to at least 0° C. for at least one of the separate cabinets and is set to at least −20° C. for at least another one or more of the separate cabinets.

17. The system of claim 15, wherein the operating temperature is determined by the controller as a point when a temperature within each of the separate cabinets is above a present dew point.

18. The system of claim 17, wherein the controller is configured to control the one or more heaters until the temperature of each of the separate cabinets is above the present dew point.

19. The system of claim 15, wherein the dispenser is coupled to an external power source and coupled to one or more electrical charger devices.

20. The system of claim 15, wherein the controller is configured determine an environmental fault condition and to disable charging if the environmental fault condition exists.
